(19) United States
(12) Patent Application Publication
(10) Pub. No.: US 2019/0249298 A1
(43) Pub. Date: Aug. 15, 2019

(54) FILM FORMING APPARATUS

(71) Applicants: NOBORU SUDA, TOKYO-TO (JP); TAKAHIRO OISHI, KANAGAWA (JP); JUNJI KOMENO, KANAGAWA (JP); CHE-LIN CHEN, TAINAN CITY (TW); YI-HUNG LIU, HSINCHU COUNTY (TW)

(72) Inventors: NOBORU SUDA, TOKYO-TO (JP); TAKAHIRO OISHI, KANAGAWA (JP); JUNJI KOMENO, KANAGAWA (JP); CHE-LIN CHEN, TAINAN CITY (TW); YI-HUNG LIU, HSINCHU COUNTY (TW)

(21) Appl. No.: 16/263,218

(22) Filed: Jan. 31, 2019

(30) Foreign Application Priority Data
Feb. 9, 2018 (JP) 2018-22258

(51) Int. Cl. C23C 16/458

(52) U.S. Cl. CPC C23C 16/4584

(57) ABSTRACT

The present invention provides a film forming apparatus capable of enabling source gases to isotropically flow and reducing the size of its chamber. When a susceptor with substrate holders containing substrates moves downward, the substrate holders are combined with a clutch mechanism. When a driving motor runs, a rotating shaft conformably rotates. The rotation is transmitted to a central gear through the clutch mechanism so as to rotate the central gear. Thus, the substrate holder whose peripheral surface is engaged with the center gear accordingly rotates so as to rotate the substrates. When the driving motor runs, a revolving shaft conformably rotates. The rotation is transmitted to the susceptor through a revolving clutch mechanism so as to rotate the susceptor and revolve the substrates. Process gases are fed via an inlet so that expected films are formed on the substrates when the substrates are at rotation and revolution statuses.

### CROSS-REFERENCE TO RELATED APPLICATION

This application claims priority from Japanese Patent Application No. 2018-22258 filed on Feb. 9, 2018, which are hereby incorporated herein by reference in its entirety.

### BACKGROUND OF THE INVENTION

### 1. Field of the Invention

The invention relates to a film forming apparatus for forming a film on a substrate via vapor phase growth, and particularly, to the improvement in a rotation driving mechanism for rotating and revolving substrates.

### 2. Description of Related Art

As background art for rotating a film deposited substrates, for example, the patent literature 1 as described below recites “a film forming apparatus including substrate rotation driving mechanism” which uses a base plate to rotatably sustain a susceptor and the circumference of the susceptor is driven to rotate through a revolution generating portion. On the other hand, plural substrate tray sustainers disposed on the susceptor rotatably sustain ring-shaped substrate trays.

### PRIOR ART LITERATURE

### Patent Literature

Patent Literature 1: Japanese Laid-Open patent publication 2002-175992

However, in view of the foregoing background art, the flow model of the source gas is not isotropic in the circumferential direction of revolution since the revolution generation portion (i.e. driving gear) at the outermost circumference. Further, the driving gear is disposed on the outer circumferential side of the susceptor so that the chamber needs to widen in the radial direction of the susceptor. Thus, the size of the chamber became large, and a gear module formed on the outer circumference of the susceptor may cause a rise in the cost and a reduction in the durability.

The present invention focuses on the above points, and its purpose is to provide a film forming apparatus capable of letting the source gases isotropically flow and reducing the chamber size.

### SUMMARY OF THE INVENTION

The present invention provides a film forming apparatus. The apparatus has a gas introduction portion for film formation, an exhaust portion, and substrate holders containing substrates for film formation, the substrate holders rotatably mounted on a susceptor, and the susceptor disposed within a chamber; a central gear engaged with the plurality of substrate holders disposed at the center of the susceptor, and the central gear joined to a rotating shaft for driving rotation, thereby rotating the substrates; a revolving shaft disposed outside the rotating shaft, and the revolving shaft joined to the susceptor so as to rotatably drive the susceptor, thereby revolving the substrates. That is, the rotation driving and the revolution driving are executed on the central side of the susceptor.

According to one of the main embodiments, a clutch mechanism is provided on the rotating shaft and the revolving shaft. Further, the clutch mechanism is structured to allow the susceptor to move upward and downward. According to another embodiment, the rotating shaft and the revolving shaft are independently driven by motor means. According to another embodiment, a thermal insulating structure is provided between the revolving shaft and the susceptor. Further according to another embodiment, the isotropic exhaust portion is slit-shaped or has equally spaced successive exhaust holes around the susceptor.

The above and other objectives, features, and advantages of the present invention are clearly clarified by the following detailed description and brief description of the drawings.

In view of the present invention, both the rotation and the revolution of the substrate are performed on the central side of the susceptor. Thus, film forming gases can isotropically flow within the chamber, and the film accordingly has uniform distribution of quality within a substrate and among substrates. Furthermore, it is possible to reduce the size of the chamber.

### BRIEF DESCRIPTION OF THE DRAWINGS

In order to sufficiently understand the essence, advantages and the preferred embodiments of the present invention, the following detailed description will be more clearly understood by referring to the accompanying drawings.

FIG. 1 illustrates a main cross-sectional diagram of the first embodiment of the present invention;

FIGS. 2(A)-2(C) are diagrams showing plane configurations of the foregoing embodiment and the background art;

FIGS. 3(A)-3(C) illustrate diagrams of the clutch mechanism of the foregoing embodiment;

FIG. 4 illustrates a diagram of the clutch mechanism of the foregoing embodiment;

FIGS. 5(A) and (B) are diagrams showing a comparison between the chambers of the foregoing embodiment and the background art;

FIG. 6 is a diagram showing the main part of the second embodiment of the present invention;

FIGS. 7(A) and (7B) are diagrams showing the main part of the third embodiment of the present invention.

### DETAILED DESCRIPTION OF THE INVENTION

The following description shows the preferred embodiments of the present invention. The present invention is described below by referring to the embodiments and the figures. Thus, the present invention is not intended to be limited to the embodiments shown, but is to be accorded the principles disclosed herein. Furthermore, that various modifications or changes in light thereof will be suggested to persons skilled in the art and are to be included within the spirit and purview of this application and scope of the appended claims.

### Embodiment 1

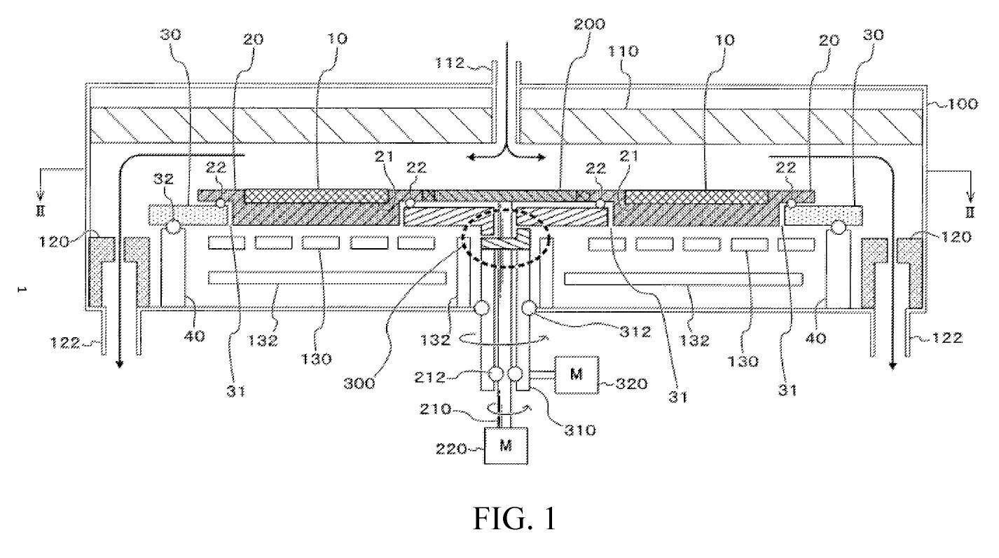

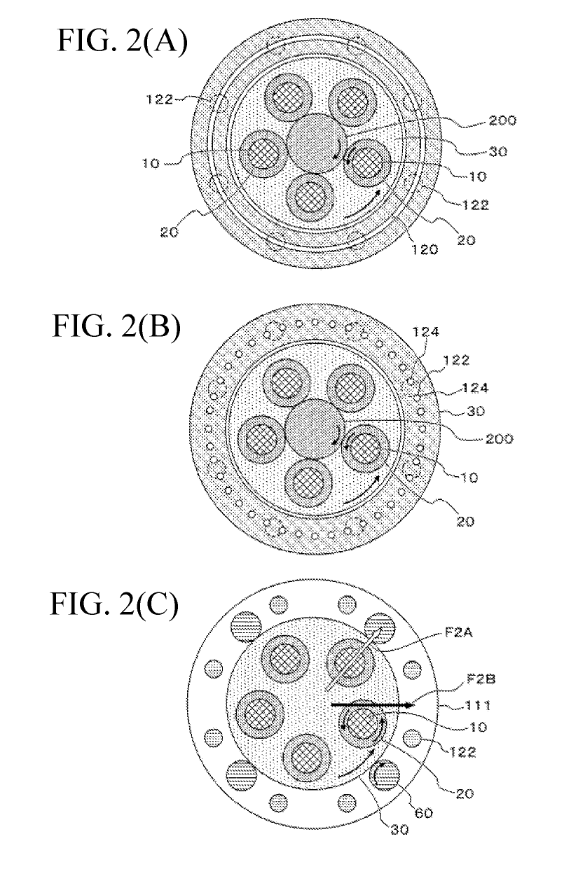

First, referring to FIGS. 1 to 5, the first embodiment of the present invention will be described hereinafter. FIG. 1 illustrates a main cross-section of a film forming apparatus regarding the present embodiment, and FIG. 2 (A) is the diagram taken along arrowed line II-II shown in FIG. 1 as viewed in the direction of the arrows. In these figures, a disk-like substrate 10 on which a film is to be formed is accommodated in a recess 21 disposed at the center of a substrate holder (a substrate tray) 20. The plural substrate holders 20 are rotatably disposed in plural openings 31 which are provided on the susceptor 30 in a radial manner at equal angles via bearings 22. The susceptor 30 is rotatably supported on a cylindrical support 40 via a bearing 32, and the support base 40 is fixed to the bottom surface of the chamber 100.

A central gear 200 is disposed at the center of the chamber 100, and is meshed with the gear provided on the outer circumference of the substrate holders 20. The spindle of the central gear 200 acts as a rotating shaft 210. A clutch mechanism 300 is provided to interpose the rotating shaft 210. Accordingly, the rotational driving force of the driving motor 220 is transmitted to the central gear 200 through the rotating shaft 210 and the clutch mechanism 300. The clutch mechanism 300 is composed of a rotating clutch 400 and a revolving clutch 500.

On the other hand, the above-mentioned rotating shaft 210 rotatably passes the center of the susceptor 30. A cylindrical revolving shaft 310 is provided to surround the rotation shaft 210 and is joined to the susceptor 30. The clutch mechanism 300 is provided to interpose the revolving shaft 310. As a result, the rotational driving force of the driving motor 320 is transmitted to the susceptor 30 through the revolving shaft 310 and the clutch mechanism 300.

A sealing (vacuum sealing) 212 comprising an O ring, a magnetic fluid or the like is provided between the rotating shaft 210 and the revolving shaft 310, and a sealing 312 is provided between the revolving shaft 310 and the chamber 100. Thus, the chamber 100 are kept airtight because of the sealing parts, and the rotating shaft 210 and the revolving shaft 310 can respectively execute independent rotating driving.

The entirety of the chamber 100 is formed in a cylindrical shape, and the opposing plate 110 is provided on the upper inner side. At the center of the upper surface, a process gas (material gas) inlet 112 is formed in the opposing plate 110 so as to further communicate with the inner of the chamber 100. On the other hand, an isotropic exhaust portion 120, which is a ring-shaped slit, is formed on the outer periphery side of the cylindrical support base 40 at the lower end portion of the chamber 100. A plurality of exhaust holes 122 are provided at equal intervals on the lower side of the side portion of the chamber 100, and are connected to the isotropic exhaust portion 120. It is to be noted that the isotropic exhaust part 120 is not formed in a slit shape. As shown in FIG. 2 (B), a large number of exhaust holes 124 provided at equal intervals on the circumference may be used.

Furthermore, a heater 130 for heating the substrates is provided on the lower side of the above-mentioned susceptor 30. Reflectors 132 for reflecting the heat of the heater 130 is provided between the heater 130 and the chamber 100 and between the heater 130 and the revolving shaft 310.

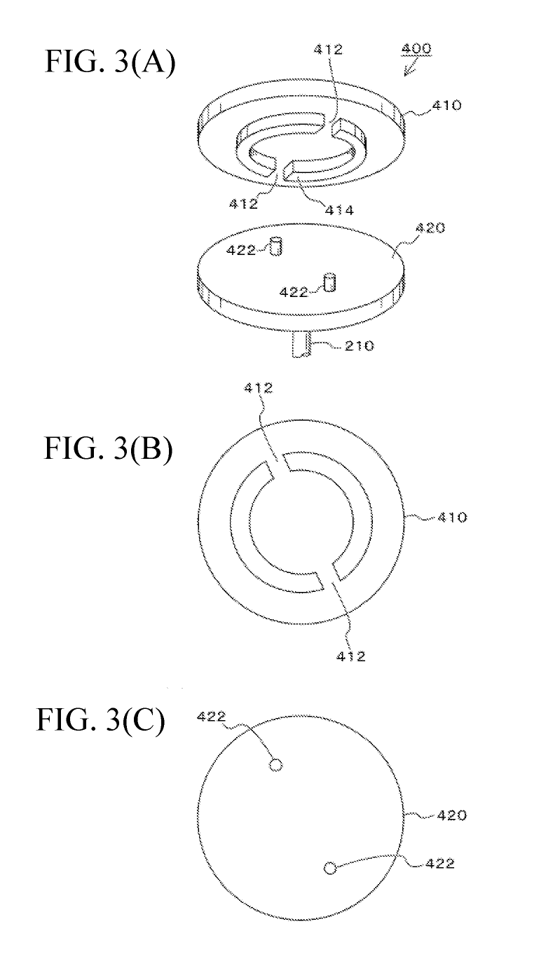

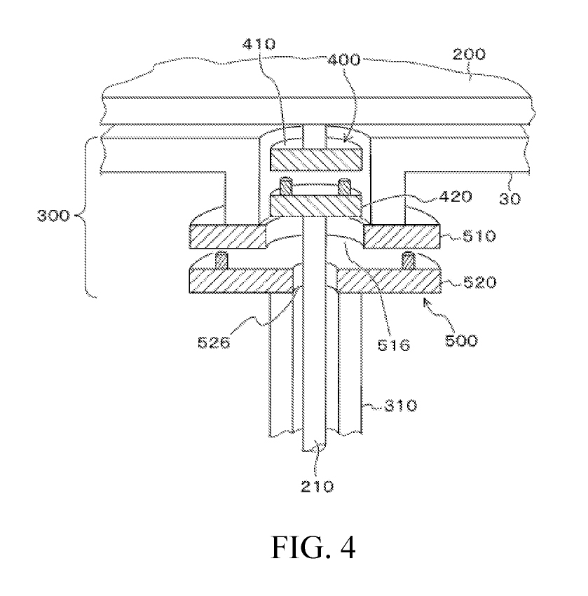

Next, with reference to FIGS. 3 to 4, the above-mentioned clutch mechanism 300 will be further described. FIG. 3(A) shows a perspective view of an example of the rotating clutch 400, and FIGS. 3(B) and 3(C) show the configurations of the main surface of each part. FIG. 4 shows the overall configuration of the clutch mechanism 300. In these figures, the rotating clutch 400 includes a concave clutch plate 410 and a convex clutch plate 420, and both of them are opposed to each other and interposed by the rotating shaft 210. An annular portion 414 is provided on the concave clutch plate 410, and engaging grooves 412 are formed in the annular portion 414. On the other hand, protrusions 422 are provided on the convex clutch plate 420. These protrusions 422 are engaged with the foregoing engagement grooves 412 so that the rotation of the rotating shaft 210 is transmitted to the central gear 200. The same is true for the revolving clutch 500 which comprises a concave clutch plate 510 and a convex clutch plate 520. However, compared with the concave and convex clutch plates 410 and 420, the concave and convex clutch plate 510 and 520 differ from them in openings 516 and 526 for the rotating shaft 210 to rotatably pass therein.

The whole operation of this embodiment will be described hereinafter. The substrate 10 is accommodated in the substrate holder 20. The susceptor 30 is lowered from an upper side in the drawing with the center alignment. Then, in the rotating clutch 400, the concave clutch plate 410 and the convex clutch plate 420 are engaged with each other. Moreover, in the revolution clutch 500, the concave clutch plate 510 and the convex clutch plate 520 are engaged with each other. Further, the circumferential surface of the susceptor 30 is supported by the support base 40 via the bearing 32. At this state, the driving motor 220 drives the rotating shaft 210 to accordingly rotate. The rotation is transmitted to the central gear 200 through the rotating clutch 400 and so that the central gear 200 rotates. Thus, the substrate holders 20 whose peripheral surfaces mesh with the gear 200 rotate on the susceptor 30. The rotation of the substrate 10 is accordingly performed as shown in FIG. 2. On the other hand, when the driving motor 320 is driven, the revolving shaft 310 rotates. The rotation is transmitted to the susceptor 30 through the revolving clutch 500 so that the susceptor 30 is rotated. In this way, the substrates 10 revolve.

As described above, in a state where the substrate 10 is rotating and revolving, the heater 130 is powered to heat the substrate 10 to a desired temperature and the process gas is introduced to form a desired thin film on the surface of the substrate 10. At this time, as the arrows shown in FIG. 1, the process gas lows from the center of the susceptor 30 toward its circumference, and passes through the isotropic exhaust portion 120 so as to be exhausted from the exhaust holes 122 to the outside of the chamber. The isotropic exhaust portion 120 is a ring-shaped slit which is arranged on an overall circle as shown in FIG. 2 (A) so that the process gas flows isotropically from the center to the peripheral edge.

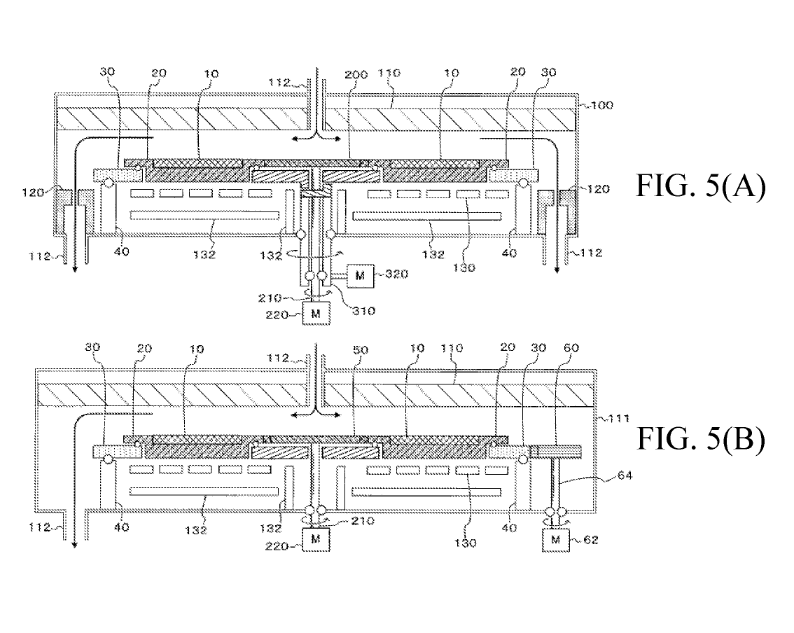

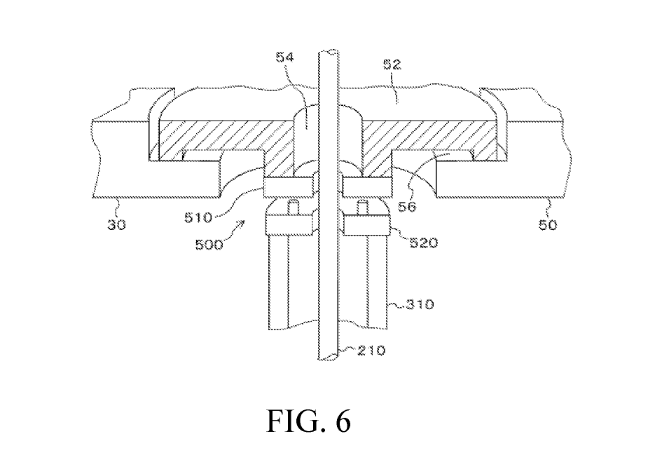

FIG. 5 is a diagram showing a comparison between the chamber size of the present embodiment and that of the foregoing background art. FIG. 5(A) shows the case of this embodiment shown in FIG. 1, and FIG. 5(B) shows the case of the background art, in which a revolving gear 60 is provided on the peripheral end side of the susceptor 30, and the driving force of a driving motor 62 is applied to the revolving gear 60 through the revolving shaft 64 so that the susceptor 30 revolves. When both of them are compared with each other, it appears that the revolving gear 60 is provided in FIG. 6(B) so that the chamber 111 of the background art is larger than that of the present embodiment. On the other hand, when the flow of the process gas is viewed in a plane as shown in FIG. 2(C), since a portion (arrowed line F2A) of the flow is obstructed by the revolving gear 60 and another portion (arrowed line F2B) of the flow is not obstructed by the revolving gear 60, the flow becomes non-uniform and is not isotropic. As described above, in this embodiment, it is possible not only to reduce the size of the chamber 100 but also to make the flow of the process gas uniform.

As described above, according to the present embodiment, both the rotation and the revolution are driven by the central shaft so that the apparatus can achieve effects in the following ways:

a, the flow of the process gas can be isotropic in the chamber so as to have uniform quality over a film within the substrate and films among the substrates.

b, it is possible to reduce the size of the chamber.

c, with the provision of the clutch, the susceptor is attached to and detached from the central gear in relative to the drive shaft so that it is possible to easily carry out the automatic conveyance of the susceptor.

d, the speed of the substrate rotation and that of the susceptor revolution can be arbitrarily set.

### Embodiment 2

Next, the second embodiment of the present invention will be described with reference to FIG. 6. As mentioned above, since the susceptor 30 is heated by the heater 130, it is at a high temperature state, but the shafts 210, 310 and the clutch mechanism 300 are at a relatively low temperature. Therefore, when they contact the hot susceptor 30, there is a possibility that a crack may occur due to a temperature difference and accordingly be damaged. In this regard, the susceptor 50 of the present embodiment is at the vicinity of the center thereof, and a dividing member 52 is provided between the susceptor 50 and the concave plate clutch 510 of the revolving clutch 500. The dividing member 52 has a donut shape and includes an opening 54 that allows a rotating shaft 210 to rotatably pass through the susceptor 50. The circumferential side edge of the dividing member 52 is connected to the susceptor 50. Further, a thermal insulating space 56 is provided between the heat insulating space 56 and the susceptor 50. By providing the dividing member 52 between the susceptor 50 and the revolving clutch 500, the dividing member 52 can be made of a material hard to conduct heat, and the heat is released by the heat insulating space 56. As a result, the heat conduction to the revolving clutch 500 and the revolving shaft 310 is reduced so that their breakage is reduced.

### Embodiment 3

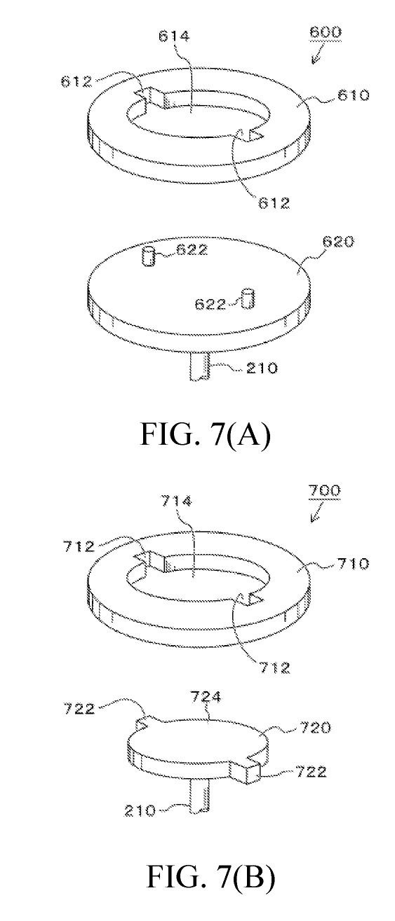

Next, the third embodiment of the present invention will be described with reference to FIG. 7. The present embodiment shows another mode of the clutch mechanism 300. In the example of FIG. 7(A), the concave clutch plate 610 of the rotating clutch 600 has an opening 614 at its center and notches 612 are formed on the opening 614. The protrusions 622 of the convex clutch plate 620 fits into the notches 612, whereby the rotation of the shaft 210 is transmitted to the central gear 200. In the example of FIG. 7(B), the central opening 714 is formed on the concave clutch plate 710 of the rotating clutch 700 and notches 712 are formed therein in the same manner as the above example. In this example, the convex clutch plate 720 is shaped to fit a circular plate 724 in the central opening 714 and contained the protrusions 722 within the notches 712. According to this example, the whole of the convex clutch plate 720 is engaged with the notches 712 and central opening 714 of the concave clutch plate 7 so that the rotation of the rotating shaft 210 is transmitted to the central gear 200. In addition, in the case of the revolving clutch, openings through which the rotating shaft 210 rotatably passes are formed at the centers of the concave and convex clutch plates.

It should be noted that the present invention is not limited to the above-described embodiments, and various modifications may be made without departing from the spirit of the present invention. Various changes can be made within a certain range. For example, the following are also included.

(1) The shapes and dimensions shown in the above embodiments are merely examples, and may be appropriately changed as necessary.
(2) In the above embodiment, the revolution type vapor phase film forming apparatus has been described as an example, but the present invention is applicable to all other apparatuses with chambers in which a film formation space is provided along a horizontal direction upon the film thickness.
(3) In the above embodiment, only the process gas for film formation is shown. Other purge gases are the same.
(4) The clutch structure shown in the above embodiment is also an example, and is appropriately modified within a range that achieves similar effects.
(5) In the above-described embodiment, the film forming surface of the substrate 10 faces upward, but the invention also can be appropriately applied to a face downward apparatus.

According to the present invention, both the rotation and the revolution of the substrate are performed on the center side of the susceptor, The flow of the film forming gas can be made isotropic in the chamber, and the uniformity of the film quality in the substrate and among the substrates can be achieved. In addition, since it is possible to reduce the size of the chamber. Thus, it can be applied to various film forming apparatuses.

The foregoing embodiments of the invention have been presented for the purpose of illustration. Although the invention has been described by certain preceding examples, it is not to be construed as being limited by them. They are not intended to be exhaustive, or to limit the scope of the invention. Modifications, improvements and variations within the scope of the invention are possible in light of this disclosure.

What is claimed is:

1. A film forming apparatus, comprising:
a gas introduction portion for film formation, an exhaust portion, and substrate holders containing substrates for film formation, the substrate holders being rotatably mounted on a susceptor, and the susceptor disposed within a chamber;
a central gear engaged with the plurality of substrate holders disposed at the center of the susceptor, and the central gear joined to a rotating shaft for driving rotation, thereby rotating the substrates;
a revolving shaft disposed outside the rotating shaft, and the revolving shaft joined to the susceptor so as to rotatably drive the susceptor, thereby revolving the substrates.

2. The film forming apparatus according to claim 1, further comprising a clutch mechanism provided on the rotating shaft and the revolving shaft.

3. The film forming apparatus according to claim 1, wherein the clutch mechanism is structured to allow the susceptor to move upward and downward.

4. The film forming apparatus according to claim 2, wherein the clutch mechanism is structured to allow the susceptor to move upward and downward.

5. The film forming apparatus according to claim 1, further comprising motor means provided to independently drive the rotating shaft and the revolving shaft.

6. The film forming apparatus according to claim 2, further comprising motor means provided to independently drive the rotating shaft and the revolving shaft.

7. The film forming apparatus according to claim 3, further comprising motor means provided to independently drive the rotating shaft and the revolving shaft.

8. The film forming apparatus according to claim 1, further comprising a thermal insulating structure provided between the revolving shaft and the susceptor.

9. The film forming apparatus according to claim 2, further comprising a thermal insulating structure provided between the revolving shaft and the susceptor.

10. The film forming apparatus according to claim 3, further comprising a thermal insulating structure provided between the revolving shaft and the susceptor.

11. The film forming apparatus according to claim 5, further comprising a thermal insulating structure provided between the revolving shaft and the susceptor.

12. The film forming apparatus according to claim 1, wherein the isotropic exhaust portion is slit-shaped or has equally spaced successive exhaust holes around the susceptor.

13. The film forming apparatus according to claim 2, wherein the isotropic exhaust portion is slit-shaped or has equally spaced successive exhaust holes around the susceptor.

14. The film forming apparatus according to claim 3, wherein the isotropic exhaust portion is slit-shaped or has equally spaced successive exhaust holes around the susceptor.

15. The film forming apparatus according to claim 5, wherein the isotropic exhaust portion is slit-shaped or has equally spaced successive exhaust holes around the susceptor.

16. The film forming apparatus according to claim 8, wherein the isotropic exhaust portion is slit-shaped or has equally spaced successive exhaust holes around the susceptor.
